(19) United States
(12) Patent Application Publication
(10) Pub. No.: US 2021/0327975 A1
(43) Pub. Date: Oct. 21, 2021

(54) ARRAY SUBSTRATE AND DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventors: Tiyao Ma, Wuhan (CN); Hong Fang, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/337,827

(22) PCT Filed: Nov. 1, 2018
(86) PCT No.: PCT/CN2018/113343

§ 371 Date: Mar. 28, 2019

(30) Foreign Application Priority Data
Aug. 30, 2018 (CN) 201811002451.3

(51) Int. Cl. H01L 27/32; H01L 51/52

(52) U.S. Cl. CPC H01L 27/3244; H01L 51/5237; H01L 51/5293

(57) ABSTRACT

The present application provides an array substrate and a display panel, the display panel comprising an array substrate, the array substrate comprising a gate having a slope and an active layer. The active layer comprises a first region parallel to the substrate, a second region parallel to the first slope, and a third region connected to the second region and parallel to the substrate.

### CROSS REFERENCE TO RELATED APPLICATION

This application claims the priority of International Application No. PCT/CN2018/113343, filed on 2018 Nov. 1, which claims priority to Chinese Application No. 201811002451.3, filed on 2018 Aug. 30. The entire disclosures of each of the above applications are incorporated herein by reference.

### BACKGROUND OF INVENTION

### Field of Invention

The present invention relates to the field of display technologies, and in particular, to an array substrate and display panel.

### Description of Prior Art

A liquid crystal display (LCD) is a widely used flat panel display, which mainly realizes screen display by modulating intensity of a backlight light field through a liquid crystal switch.

At present, the display resolution of displays in small-sized mobile phones on the market is constantly increasing, and as the commercialization of virtual display (VR) becomes more and more mature, display products with high resolution and high refresh rate become the commanding heights of future development. The key to improving the display resolution is to continuously reduce the display size of the thin film transistor (TFT) device, and the conventional reduction of the size of the TFT device is highly challenging reliability of the product.

In addition, channel length is a key factor in the manufacture of high resolution array substrates, especially for driving thin film transistors in LCD and organic light emitting diode display devices, the channel length can be dozens of microns and occupy a large area, which goes against high resolution.

### SUMMARY OF INVENTION

The present application provides an array substrate and a display panel to solve the technical problem that the display resolution of the existing display panel is low.

In order to solve the above problem, the technical solutions provided by the present application are as follows:

The present application provides an array substrate, comprising:

a substrate;

a buffer layer on the substrate;

a first gate on the buffer layer, the first gate comprising a first slope;

a gate insulating layer on the first gate;

an active layer on the gate insulating layer, and the active layer comprising a first region parallel to the substrate, a second region parallel to the first slope, and a third region connected to the second region and parallel to the substrate;

a spacer insulating layer on the active layer;

a source and a drain on the spacer insulating layer, the source and the drain electrically connected to the active layer; and

a planar layer on the source and the drain.

In the array substrate of the present application, the source is electrically connected to the first region of the active layer, and the drain is electrically connected to the third region of the active layer.

In the array substrate of the present application, the spacer insulating layer is provided with a first via hole and a second via hole which are spaced from one another, the source is electrically connected to the first region through the first via hole, and the drain is electrically connected to the third region through the second via hole.

In the array substrate of the present application, the first region comprises a first doped region; the third region comprises a second doped region; the source is electrically connected to the first doped region through the first via hole, the drain is electrically connected to the second doped region through the second via hole.

In the array substrate of the present application, the first gate further comprises a second slope corresponding to the first slope.

In the array substrate of the present application, the array substrate further comprises a second gate, and the second gate and the first gate are disposed in the same layer and spaced from one another.

In the array substrate of the present application, the second gate comprises a third slope opposite to the first slope.

In the array substrate of the present application, the active layer further comprises a fourth region connected to the third region and parallel to the third slope, and a fifth region connected to the fourth region and parallel to the substrate.

In the array substrate of the present application, the first region comprises a first doped region; the fifth region comprises a third doped region; the source is electrically connected to the first doped region, and the drain is electrically connected to the third doped region.

In the array substrate of the present application, the first gate and the second gate have a trapezoidal cross section, a cross section of the first gate is perpendicular to the first gate and a longitudinal direction of the first gate, and the cross section of the second gate is perpendicular to the second gate and a longitudinal direction of the second gate.

The present application also provides a display panel, which comprises an array substrate, a light emitting device layer, a thin film encapsulating layer, a polarizer layer and a cover plate on the array substrate.

Advantageous effects: by setting the active layer to a bent shape, the present application reduces the projected length of the active layer on the substrate, decreases the area of the thin film transistor unit in each of the array substrates, increases the number of thin film transistor units in the array substrate, and improves the resolution of the display panel.

### BRIEF DESCRIPTION OF DRAWINGS

In order to describe clearly the embodiment in the present disclosure or the prior art, the following will introduce the drawings for the embodiment shortly. Obviously, the following description is only a few embodiments, for the common technical personnel in the field it is easy to acquire some other drawings without creative work.

FIG. 1 is a structure diagram of film layers of an array substrate according to embodiment 1 of the present application;

FIG. 2 is a structure diagram of a first film layer of the gate region of FIG. 1.

FIG. 3 is a structure diagram of a second film layer of the gate region of FIG. 1.

FIG. 4 is a structure diagram of film layers of an array substrate according to embodiment 2 of the present application;

FIG. 5 is a structure diagram of a first film layer of the gate region of FIG. 4.

FIG. 6 is a structure diagram of a second film layer of the gate region of FIG. 4.

FIG. 7 is a structural diagram of film layers of a display panel of the present application.

### DETAILED DESCRIPTION OF PREFERRED EMBODIMENTS

The description of following embodiment, with reference to the accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present disclosure. In the drawings, the components having similar structures are denoted by same numerals.

### Embodiment 1

Please refer to FIG. 1, wherein FIG. 1 is a structure diagram of film layers of an array substrate according to embodiment 1 of the present application.

The array substrate 100 comprises a substrate 101, a flexible substrate film layer 102 on the substrate 101, a buffer layer 103, a first gate 104, a gate insulating layer 105, an active layer 106, an interlayer insulating layer 107, a source and drain layers 108, and a flat layer 109.

In one embodiment, the substrate 101 could be one of a glass substrate, a quartz substrate, a resin substrate and the like, as a base substrate of the array substrate 100.

In one embodiment, the substrate 101 is not an essential feature. In other embodiments, the substrate 101 may not be provided.

The flexible substrate film layer 102 is positioned on the substrate 101.

In one embodiment, the flexible substrate film layer 102 could be a polyimide film, as a substrate for a flexible display panel. The flexible substrate film layer 102 has a thickness of 10 to 20 um.

The buffer layer 103 is positioned on the flexible substrate film layer 102, and the buffer layer 103 covers the flexible substrate film layer 102 to buffer the downward pressure of the upper film layer.

In one embodiment, the material of the buffer layer 103 could be silicon oxide, or a composite layer structure of silicon oxide and silicon nitride.

In one embodiment, the buffer layer 103 has a thickness of 300 to 800 nm.

The first gate 104 is positioned on the buffer layer 103. The metal material of the first gate electrode 104 could be metal such as molybdenum, aluminum, aluminum-nickel alloy, molybdenum-tungsten alloy, chromium, or copper, or a combination of the above-mentioned metal materials.

In an embodiment, the metal material of the first gate 104 could be molybdenum.

In one embodiment, the first gate 104 has a thickness of 500 to 1000 nm.

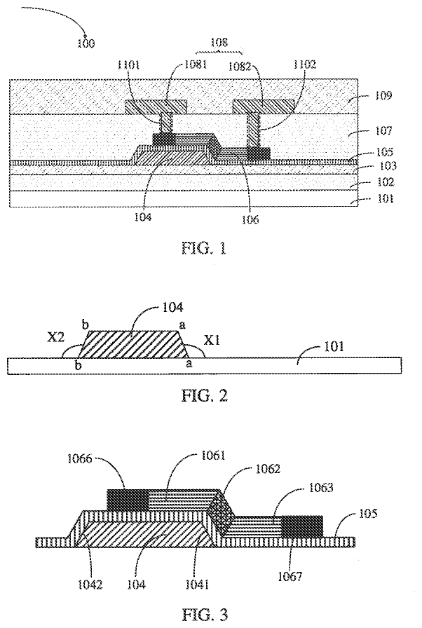

Please refer to FIG. 2. FIG. 2 is a structure diagram of a first film layer of the gate region of FIG. 1.

The first gate 104 comprises a first slope “aa” and a second slope “bb”.

In an embodiment, the cross section of the first gate 104 could be trapezoidal.

The angle between the first slope and the substrate 101 is A, and the angle between the second slope and the substrate 101 is B, and 45°≤A<90°, 45°≤B<90°.

In one embodiment, 45°≤A≤80°, 45°≤B≤80°, and angle A and angle B could be equal. The cross section of the first gate 104 is a cross section perpendicular to the first gate 104 and the longitudinal direction of the first gate 104.

Please refer to FIG. 3. FIG. 3 is a structure diagram of a second film layer of the gate region of FIG. 1.

As shown in FIG. 1 and FIG. 3, the gate insulating layer 105 is formed on the first gate 104 to cover the first gate 104. The gate insulating layer 105 is mainly used to isolate the first gate 104 from other metal layers.

In one embodiment, the material of the gate insulating layer 105 could be silicon nitride, silicon oxide, silicon oxynitride or the like.

The active layer 106 is formed on the gate insulating layer 105, and the active layer 106 is composed of polysilicon. The active layer 106 comprises a first region 1061 parallel to the substrate 101, and a second region 1062 parallel to the first slope, and a third region 1063 that is connected to the second region 1062 and parallel to the substrate.

The active layer 106 further comprises a first doped region 1066 and a second doped region 1067, and the first doped region 1066 and the second doped region 1067 are located on each side of the active layer 106.

In one embodiment, the first doped region 1066 is located within the first region 1061, i.e., the gate insulating layer 105 on the first gate 104. The second doped region 1067 is located in the third region 1063 away from the gate insulating layer 105 of the first gate 104.

The interlayer insulating layer 107 is formed on the active layer 106, and the interlayer insulating layer 107 covers the active layer 106. The interlayer insulating layer 107 is mainly used to isolate the active layer 106 and the source and drain layer 108.

The source and drain layers 108 are formed on the interlayer insulating layer 107, and the source and drain layer 108 comprises a source 1081 and a drain 1082.

In one embodiment, the metal material of the source and drain layer 108 could be metal such as molybdenum, aluminum, aluminum-nickel alloy, molybdenum-tungsten alloy, chromium, copper or titanium aluminum alloy, and also could be a combination of the above-mentioned metal materials.

In an embodiment, the source and drain layers 108 could be titanium aluminum alloy.

The flat layer 109 is formed on the source and drain layers 108, and the flat layer 109 covers the source and drain layer 108 and is mainly used to ensure the planarity of the film layer structure.

In an embodiment, the array substrate 100 further comprises a first via hole 1101 and a second via hole 1102 spaced from one another on the interlayer insulating layer 107. The source 1081 is electrically connected to the first region 1061 through the first via hole 1101, and the drain 1082 is electrically connected to the third region 1063 through the second via hole 1102.

The source 1081 is electrically connected to the first doped region 1066 through the first via hole 1101, and the drain 1082 is electrically connected to the second doped region 1067 through the second via hole 1102.

### Embodiment 2

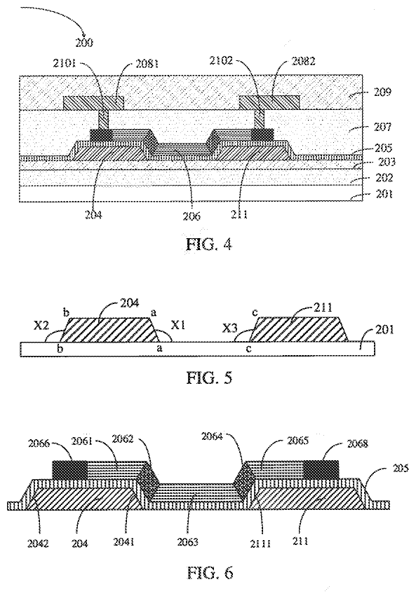

Please refer to FIG. 4, wherein FIG. 4 is a structure diagram of film layers of an array substrate according to embodiment 2 of the present application.

This embodiment is the same as or similar to the specific embodiment 1, except that:

The array substrate 200 further comprises a second gate 211, and the second gate 211 is spaced apart from the first gate 204. The second gate 211 and the first gate 204 are made of a same metal layer in a same mask process.

As shown in FIG. 5, wherein FIG. 5 is a structure diagram of a first film layer of the gate region of FIG. 4.

The second gate 211 comprises a third slope “cc” corresponding to the first slope “aa” of the first gate 201.

In one embodiment, the second gate 211 has a trapezoidal cross section.

In an embodiment, the cross-sectional shapes of the first gate 204 and the second gate 211 could be same or different.

In one embodiment, the first gate 204 and the second gate 211 have the same cross-sectional shape.

The angle between the third slope “cc” and the substrate 201 is C, and 45°≤C<90°. In one embodiment, 45°≤C≤80°.

The cross section of the second gate electrode 211 is a cross section perpendicular to the second gate electrode 211 and the longitudinal direction of the second gate electrode 211.

As shown in FIG. 6, wherein FIG. 6 is a structure diagram of a second film layer of the gate region of FIG. 4.

The active layer 206 is U-shaped. The active layer 206 comprises a first region 2061 parallel to the substrate 201, a second region 2062 parallel to the first slope, a third region 2063 connected to the second region 2062 and parallel to the substrate 201, a fourth region 2064 connected to the third region 2063 and parallel to the third slope, and a fifth region 2065 connected to the fourth region 2064 and parallel to the substrate 201. The first region 2061 comprises a first doped region 2066, and the fifth region 2065 comprises a third doped region 2068. The source 2081 is electrically connected to the first doped region 2066, and the drain 2082 is electrically connected to the third doped region 2068.

For the first embodiment and the second embodiment, the active layer is formed by crystallization by excimer laser annealing (ELA). Since the gate of the array substrate has a certain slope angle, the formed active layer also has the same slope angle as the gate. Therefore, the present application needs to adjust the emitting angle of the laser emitting section of the corresponding device, that is, without changing the optical splitting path, an optical angle adjusting mirror group is added to deflect the final light emitting angle of the laser.

In one embodiment, the deflection angle is 10 to 45°, so that the laser directly illuminates the edge of the slope of the gate to ensure uniformity of crystallization of the vertical region of the active layer 106.

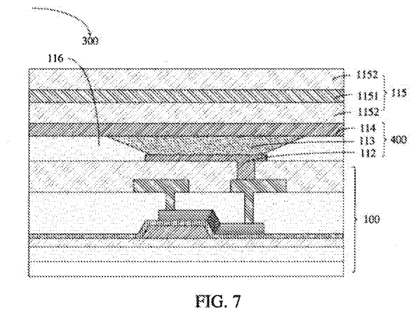

As shown in FIG. 7, wherein FIG. 7 is a structural diagram of film layers of a display panel of the present application.

The display panel 300 further comprises an array substrate 100, a light emitting device layer 400 on the array substrate 100, a thin film encapsulation layer 115, a polarizer layer (not shown), and a cover plate (not shown).

The array substrate could be any one of embodiment 1 and embodiment 2. The specific structure is not described in detail. The following is an example of an array substrate according to embodiment 1.

The light emitting device layer 400 comprises an anode layer 112, a light emitting layer 113, and a cathode layer 114 on the array substrate 100.

The anode layer 112 is positioned on the flat layer 109 in the array substrate 100. The anode layer 112 comprises at least two anodes arranged in an array.

In one embodiment, the OLED device is a top emission type OLED device, which is a white OLED device emitting white light. Therefore, the anode layer 112 is a non-transparent light blocking layer.

The light emitting layer 113 is positioned on the anode layer 112. The light emitting layer 113 comprises a plurality of light emitting units, and adjacent light emitting units are separated by the pixel defining layer 116 to prevent crosstalk of colors.

The cathode layer 114 is positioned on the light emitting layer 113.

In one embodiment, the cathode layer 114 is a transparent material, so that light emitted by the light emitting layer 113 is projected outward through the cathode layer 114.

The thin film encapsulation layer 115 is located on the cathode layer 114. The thin film encapsulation layer 115 is used for blocking external water and oxygen, and preventing external water from eroding the organic light emitting layer. The thin film encapsulation layer 115 comprises at least one organic layer 1151 and at least one inorganic layer 1152 alternately stacked.

In one embodiment, the thin film encapsulation layer 115 comprises an organic layer 1151 and two inorganic layers 1152 alternately arranged.

The present application provides an array substrate and a display panel, the display panel comprising an array substrate, the array substrate comprising a gate having a slope and an active layer. The active layer comprises a first region parallel to the substrate, a second region parallel to the first slope, and a third region connected to the second region and parallel to the substrate. By setting the active layer to a bent shape, the present application reduces the projected length of the active layer on the substrate, decreases the area of the thin film transistor unit in each of the array substrates, increases the number of thin film transistor units in the array substrate, and improves the resolution of the display panel.

As is understood by persons skilled in the art, the foregoing preferred embodiments of the present disclosure are illustrative rather than limiting of the present disclosure. It is intended that they cover various modifications and that similar arrangements be comprised in the spirit and scope of the present disclosure, the scope of which should be accorded the broadest interpretation so as to encompass all such modifications and similar structures.

What is claimed is:

1. An array substrate, comprising:
a substrate;
a buffer layer on the substrate;
a first gate on the buffer layer, the first gate comprising a first slope;
a gate insulating layer on the first gate;
an active layer on the gate insulating layer, and the active layer comprising a first region parallel to the substrate, a second region parallel to the first slope, and a third region connected to the second region and parallel to the substrate;
a spacer insulating layer on the active layer;
a source and a drain on the spacer insulating layer, the source and the drain electrically connected to the active layer; and
a planar layer on the source and the drain.

2. The array substrate according to claim 1, wherein the source is electrically connected to the first region of the active layer, and the drain is electrically connected to the third region of the active layer.

3. The array substrate according to claim 1, wherein the spacer insulating layer is provided with a first via hole and a second via hole which are spaced from one another, the source is electrically connected to the first region through the first via hole, and the drain is electrically connected to the third region through the second via hole.

4. The array substrate according to claim 3, wherein the first region comprises a first doped region; the third region comprises a second doped region; the source is electrically connected to the first doped region through the first via hole, the drain is electrically connected to the second doped region through the second via hole.

5. The array substrate according to claim 1, wherein the first gate further comprises a second slope corresponding to the first slope.

6. The array substrate according to claim 1, wherein the array substrate further comprises a second gate, and the second gate and the first gate are disposed in the same layer and spaced from one another.

7. The array substrate according to claim 6, wherein the second gate comprises a third slope opposite to the first slope.

8. The array substrate according to claim 7, wherein the active layer further comprises a fourth region connected to the third region and parallel to the third slope, and a fifth region connected to the fourth region and parallel to the substrate.

9. The array substrate according to claim 8, wherein the first region comprises a first doped region; the fifth region comprises a third doped region; the source is electrically connected to the first doped region, and the drain is electrically connected to the third doped region.

10. The array substrate according to claim 7, wherein the first gate and the second gate have a trapezoidal cross section, a cross section of the first gate is perpendicular to the first gate and a longitudinal direction of the first gate, and the cross section of the second gate is perpendicular to the second gate and a longitudinal direction of the second gate.

11. A display panel, which comprises an array substrate, a light emitting device layer, a thin film encapsulating layer, a polarizer layer and a cover plate on the array substrate, wherein the array substrate comprises:
a substrate;
a buffer layer on the substrate;
a first gate on the buffer layer, and the first gate comprising a first slope;
a gate insulating layer on the first gate;
an active layer on the gate insulating layer, and the active layer comprising a first region parallel to the substrate, a second region parallel to the first slope, and a third region connected to the second region and parallel to the substrate;
a spacer insulating layer on the active layer;
a source and a drain on the spacer insulating layer, and the source and the drain are electrically connected to the active layer respectively; and
a planar layer on the source and the drain.

12. The display panel according to claim 11, wherein the source is electrically connected to the first region of the active layer, and the drain is electrically connected to the third region of the active layer.

13. The display panel according to claim 11, wherein the spacer insulating layer is provided with a first via hole and a second via hole which are spaced from one another, the source is electrically connected to the first region through the first via hole, and the drain is electrically connected to the third region through the second via hole.

14. The display panel according to claim 13, wherein the first region comprises a first doped region; the third region comprises a second doped region; the source is electrically connected to the first doped region through the first via hole; the drain is electrically connected to the second doped region through the second via hole.

15. The display panel according to claim 11, wherein the first gate further comprises a second slope corresponding to the first slope.

16. The display panel according to claim 11, wherein the display panel further comprises a second gate, and the second gate and the first gate are disposed in the same layer and spaced from one another.

17. The display panel according to claim 16, wherein the second gate comprises a third slope opposite to the first slope.

18. The display panel according to claim 17, wherein the active layer further comprises a fourth region connected to the third region and parallel to the third slope, and a fifth region connected to the fourth region and parallel to the substrate.

19. The display panel according to claim 18, wherein the first region comprises a first doped region; the fifth region comprises a third doped region; the source is electrically connected to the first doped region, and the drain is electrically connected to the third doped region.

20. The display panel according to claim 17, wherein the first gate and the second gate have a trapezoidal cross section, a cross section of the first gate is perpendicular to the first gate and a longitudinal direction of the first gate, and the cross section of the second gate is perpendicular to the second gate and a longitudinal direction of the second gate.
